(19) United States
(12) Patent Application Publication
(10) Pub. No.: US 2025/0253296 A1
(43) Pub. Date: Aug. 7, 2025

(54) SEMICONDUCTOR PACKAGE AND METHOD OF MANUFACTURING THE SAME

(71) Applicant: Samsung Electronics Co., Ltd., Suwon-si (KR)

(72) Inventors: Junghoo Yun, Suwon-si (KR); Jihwang Kim, Suwon-si (KR)

(21) Appl. No.: 18/815,863

(22) Filed: Aug. 27, 2024

(30) Foreign Application Priority Data
Feb. 7, 2024 (KR) 10-2024-0019178

(51) Int. Cl. H01L 25/16; H01L 23/00; H01L 23/31; H01L 23/48; H01L 23/498; H01L 23/538; H10B 80/00

(52) U.S. Cl. CPC H01L 25/162; H01L 23/481; H01L 24/16; H01L 24/24; H01L 23/3185; H01L 23/49811; H01L 23/538; H01L 2224/16227; H01L 2224/24145; H10B 80/00

(57) ABSTRACT

There are provided a semiconductor package capable of maximizing heat dissipation characteristics and implementing a small form factor and a method of manufacturing the same. The semiconductor package includes a first redistribution substrate, a first semiconductor chip arranged on the first redistribution substrate on a right side in a first direction and including through electrodes, first through posts arranged on the first redistribution substrate on a left side in the first direction on a side of the first semiconductor chip, a second redistribution substrate arranged on the first semiconductor chip and first through posts, a semiconductor device arranged on the second redistribution substrate on a left side in the first direction, and a second semiconductor chip arranged on the second redistribution substrate on a right side in the first direction on a side of the semiconductor device.

### CROSS-REFERENCE TO RELATED APPLICATION

This application is based on and claims priority under 35 U.S.C. § 119 to Korean Patent Application No. 10-2024-0019178, filed on Feb. 7, 2024, in the Korean Intellectual Property Office, the disclosure of which is incorporated by reference herein in its entirety.

### BACKGROUND

The inventive concept relates to a semiconductor package, and more particularly, to a semiconductor package including redistribution substrates on and under a semiconductor chip and a method of manufacturing the same.

By the rapid development of the electronics industry and user demands, electronic devices are becoming smaller and lighter. As electronic devices become smaller and lighter, semiconductor packages used therein are also becoming smaller and lighter, and semiconductor packages are demanded to have high reliability along with high performance and large capacity. As performance and capacity of semiconductor packages increase, power consumption of semiconductor packages is increasing. Accordingly, the importance of reducing the size and improving the performance of semiconductor packages and heat dissipation characteristics of semiconductor packages is increasing.

### SUMMARY

The inventive concept relates to a semiconductor package capable of maximizing heat dissipation characteristics and implementing a small form factor and a method of manufacturing the same.

In addition, problems to be solved by the technical idea of the inventive concept are not limited to the above-mentioned problems, and other problems not mentioned will be clearly understood by those skilled in the art from the following description.

According to an aspect of the inventive concept, there is provided a semiconductor package including a first redistribution substrate, a first semiconductor chip arranged on the first redistribution substrate on a right side in a first direction and including through electrodes, first through posts arranged on the first redistribution substrate on a left side in the first direction on a side of the first semiconductor chip, a second redistribution substrate arranged on the first semiconductor chip and first through posts, a semiconductor device arranged on the second redistribution substrate on a left side in the first direction, and a second semiconductor chip arranged on the second redistribution substrate on a right side in the first direction on a side of the semiconductor device.

According to another aspect of the inventive concept, there is provided a semiconductor package including a first redistribution substrate, a first semiconductor chip arranged on the first redistribution substrate on a right side in a first direction and including through electrodes, a first sealant arranged on the first redistribution substrate and sealing the first semiconductor chip, first through posts arranged on the first redistribution substrate on a left side in the first direction to be side by side with the first semiconductor chip and extending through the first sealant, a second redistribution substrate arranged on the first semiconductor chip and first through posts, a semiconductor device arranged on the second redistribution substrate on a left side in the first direction, a second semiconductor chip arranged on the second redistribution substrate on a right side in the first direction to be side by side with the semiconductor device, and a second sealant arranged on the second redistribution substrate and sealing the semiconductor device and the second semiconductor chip and top surfaces of the semiconductor device and the second semiconductor chip are exposed from the second sealant.

According to another aspect of the inventive concept, there is provided a semiconductor package including a first redistribution substrate, a first semiconductor chip arranged on the first redistribution substrate and including through electrodes, a second redistribution substrate arranged on the first semiconductor chip, a semiconductor device arranged on the second redistribution substrate on a left side in a first direction, and a second semiconductor chip arranged on the second redistribution substrate on a right side in the first direction to be side by side with the semiconductor device.

According to another aspect of the inventive concept, there is provided a method of manufacturing a semiconductor package, including forming an upper redistribution substrate on a first carrier substrate, attaching a semiconductor device and a top semiconductor chip to a first surface of the upper redistribution substrate, attaching a bottom semiconductor chip to a second surface of the upper redistribution substrate opposite to the first surface, forming a lower redistribution substrate on the bottom semiconductor chip, and attaching a passive element and external connection terminals to the lower redistribution substrate and the bottom semiconductor chip comprises through electrode.

### BRIEF DESCRIPTION OF THE DRAWINGS

Embodiments will be more clearly understood from the following detailed description taken in conjunction with the accompanying drawings in which:

FIGS. 1A and 1B are respectively a plan view and a cross-sectional view of a semiconductor package according to an embodiment;

FIGS. 2A to 2C are cross-sectional views illustrating a structure of a memory device in more detail in the semiconductor package of FIG. 1B;

FIGS. 3A and 3B are plan views of semiconductor packages according to some embodiments;

FIG. 4 is a cross-sectional view of a semiconductor package according to an embodiment;

FIGS. 5A to 5J are cross-sectional views schematically illustrating processes of a method of manufacturing a semiconductor package according to an embodiment;

FIGS. 6A to 6F are cross-sectional views illustrating the process of FIG. 5E in more detail; and

FIGS. 7A to 7C are cross-sectional views schematically illustrating processes of a method of manufacturing a semiconductor package according to an embodiment.

### DETAILED DESCRIPTION OF THE EMBODIMENTS

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Hereinafter, embodiments of the inventive concept will be described in detail with reference to the accompanying drawings. Like reference numerals refer to like elements, and their repetitive descriptions are omitted.

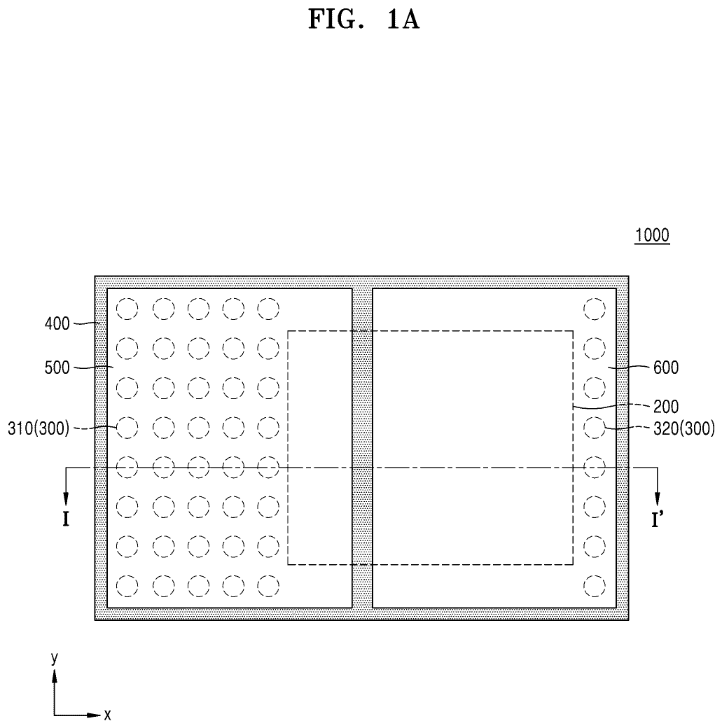

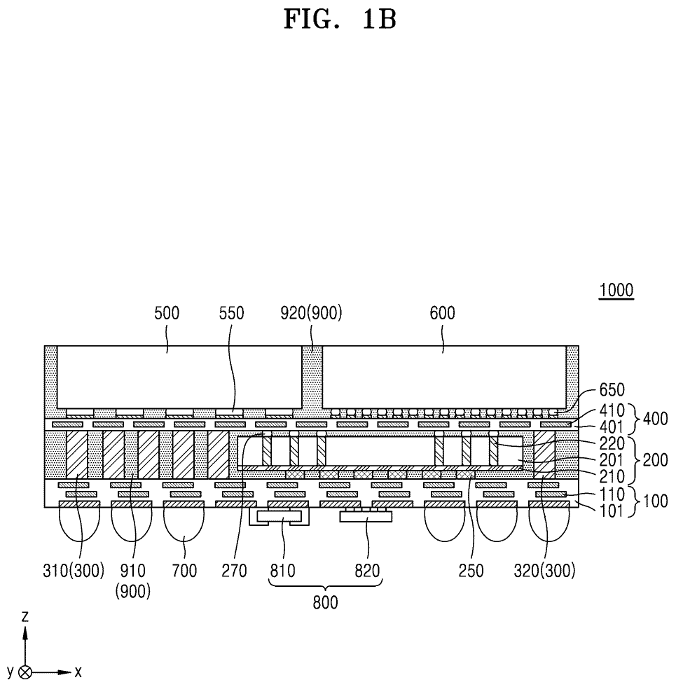

FIGS. 1A and 1B are respectively a plan view and a cross-sectional view of a semiconductor package 1000 according to an embodiment.

Referring to FIGS. 1A and 1B, the semiconductor package 1000 of the current embodiment may include a first redistribution substrate 100, a first semiconductor chip 200, through posts 300, a second redistribution substrate 400, a semiconductor device 500, a second semiconductor chip 600, external connection terminals 700, a passive element 800, and a sealant 900.

The first redistribution substrate 100 may be arranged under the first semiconductor chip 200, the through posts 300, and a first sealant 910. The first redistribution substrate 100 may redistribute chip pads of the first semiconductor chip 200 to an external region of the first semiconductor chip 200. The first redistribution substrate 100 may include a first body insulating layer 101 and a first redistribution line 110.

The first body insulating layer 101 may include an insulating material, for example, photo-imagable dielectric (PID) or photo-imagable polyimide (PIP) resin, and may further include an inorganic filler. However, the material of the first body insulating layer 101 is not limited thereto. For example, the first body insulating layer 101 may include polyimide isoindro quirazorindione (PIQ), polyimide (PI), or polybenzoxazole (PBO).

The first body insulating layer 101 may have a multilayer structure according to a multilayer structure of first redistribution lines 110. However, in FIG. 1B, for convenience, the first body insulating layer 101 is illustrated as having a single-layer structure. When the first body insulating layer 101 has a multilayer structure, all layers of the first body insulating layer 101 may include the same material, or at least one layer may include a different material.

The first redistribution lines 110 may be arranged in multiple layers in the first body insulating layer 101. The first redistribution lines 110 arranged in different layers may be connected to one another by vertical vias. For reference, the vertical vias are not illustrated in FIG. 1B. The first redistribution lines 110 and the vertical vias may include, for example, copper (Cu). However, the material of the first redistribution lines 110 and the vertical vias is not limited to Cu.

The external connection terminals 700 may be arranged on a bottom surface of the first body insulating layer 101. The external connection terminals 700 may be arranged respectively on external connection pads arranged on the bottom surface of the first body insulating layer 101. The external connection pads may be included as part of the first redistribution lines 110. However, in some embodiments, the external connection pads may be treated as a separate component from the first redistribution lines 110.

The first semiconductor chip 200 may be mounted on the first redistribution substrate 100 through first connection terminals 250. Each of the first connection terminals 250 may include a metal pillar or solder. In some embodiments, the first connection terminal 250 may include a metal pillar and/or solder (e.g., a solder ball or a solder bump). Here, the metal pillar may include, for example, Cu. However, the material of the metal pillar is not limited to Cu.

The first semiconductor chip 200 may be arranged on the first redistribution substrate 100 to be biased to one side (e.g., placed on one side) in an x direction. For example, a center of the first semiconductor chip 200 may not be disposed at a center of the first redistribution substrate 100 in a plan view, but be spaced apart from the center of the first redistribution substrate 100 in the x direction in the plan view. For example, as illustrated in FIG. 1B, the first semiconductor chip 200 may be arranged on the first redistribution substrate 100 to be biased to the right (e.g., placed on one side) in the x direction. As the first semiconductor chip 200 is biased to the right in the x direction, the second semiconductor chip 600 above the first semiconductor chip 200 may also be biased to the right. This arrangement may effectively dissipate heat generated by the first semiconductor chip 200 and the second semiconductor chip 600.

The first semiconductor chip 200 may be an analog chip. For example, the first semiconductor chip 200 may be a modem chip supporting communication with the second semiconductor chip 600. However, the type of the first semiconductor chip 200 is not limited to a modem chip. For example, the first semiconductor chip 200 may include other types of integrated devices supporting an operation of the second semiconductor chip 600. The first semiconductor chip 200 may include a multi-channel I/O interface for exchanging memory signals with the semiconductor device 500. The first semiconductor chip 200 may include static random access memory (SRAM) for temporary storage of data.

As illustrated in FIG. 1B, the first semiconductor chip 200 may include a substrate 201, an active layer 210, and through electrodes 220. The substrate 201 may constitute a body of the first semiconductor chip 200 and may be based on a silicon wafer. The active layer 210 may be arranged under the substrate 201. For example, the active layer 210 may include an integrated circuit layer on which active elements such as transistors are arranged, and a multi-layer wiring structure arranged on the integrated circuit layer. The multi-layer wiring structure may occupy most of the active layer 210, and the integrated circuit layer may occupy only part of the active layer 210. For example, the multi-layer wiring structure may include multi-layer wiring lines, and wiring lines in different layers may be connected to one another through vias. Chip pads electrically connected to the multi-layer wiring lines may be arranged on a bottom surface of the active layer 210, and the first connection terminals 250 may be respectively arranged on the chip pads.

The through electrodes 220 may extend in a vertical direction, that is, a z direction, through the substrate 201. Bottom surfaces of the through electrodes 220 may be electrically connected to (e.g., contact) the multi-layer wiring lines of the active layer 210 and top surfaces of the through electrodes 220 may be electrically connected to (e.g., contact) second connection terminals 270. For example, upper pads may be arranged on the top surfaces of the through electrodes 220, and the second connection terminals 270 may be electrically connected to the through electrodes 220 through the upper pads. Accordingly, the first semiconductor chip 200 may be electrically connected to the second redistribution substrate 400 through the through electrodes 220 and the second connection terminals 270. In addition, the first semiconductor chip 200 may be electrically connected to the second semiconductor chip 600 through a second redistribution line 410 of the second redistribution substrate 400 and fourth connection terminals 650.

Because the through electrodes 220 penetrate silicon constituting the substrate 201, each through electrode 220 may be referred to as a through silicon via (TSV). For reference, the through electrodes 220 may include a via-first structure formed before the integrated circuit layer of the active layer 210 is formed, a via-middle structure formed after the integrated circuit layer is formed and before the multi-layer wiring structure of the active layer 210 is formed, and/or a via-last structure formed after the multi-layer wiring structure is formed. In the embodiment illustrated in FIG. 1B, the through electrode 220 may correspond to or may have, for example, the via-middle structure. However, the inventive concept is not limited thereto. In the semiconductor package 1000 of the current embodiment, the through electrode 220 may have the via-first structure or the via-last structure.

In the first semiconductor chip 200, a bottom surface may be a front side that is an active surface, and a top surface may be a back side that is an inactive surface. For example, a bottom surface of the active layer 210 may correspond to or may be the front side of the first semiconductor chip 200, and a top surface of the substrate 201 may correspond to or may be the back side of the first semiconductor chip 200. The chip pads may be formed on the front side that is the active surface, and the first semiconductor chip 200 may be mounted on the first redistribution substrate 100 through the first connection terminals 250 arranged on the chip pads.

The through posts 300 may be arranged between the first redistribution substrate 100 and the second redistribution substrate 400. As the first sealant 910 is arranged between the first redistribution substrate 100 and the second redistribution substrate 400, the through posts 300 may extend in the z direction through the first sealant 910. The through posts 300 may electrically connect the first redistribution substrate 100 to the second redistribution substrate 400. For example, the through posts 300 may be electrically connected to (e.g., contact) the first redistribution line 110 of the first redistribution substrate 100, and may also be electrically connected to (e.g., contact) the second redistribution line 410 of the second redistribution substrate 400.

In the semiconductor package 1000 of the current embodiment, the through posts 300 may include first through posts 310 and second through posts 320. As noted from FIGS. 1A and 1B, the first through posts 310 may be arranged on the first redistribution substrate 100 on the left side of the first semiconductor chip 200 in the x direction. For example, the first through posts 310 may be arranged in a two-dimensional array on the first redistribution substrate 100 on the left side of the first semiconductor chip 200 in the x direction. The first through posts 310 may be electrically connected to the semiconductor device 500 through the second redistribution substrate 400.

The second through posts 320 may be arranged on the first redistribution substrate 100 on the right side of the first semiconductor chip 200 in the x direction. For example, the second through posts 320 may be arranged in a row in a horizontal direction (e.g., y direction) on the first redistribution substrate 100 on the right side of the first semiconductor chip 200 in the x direction. However, in some embodiments, the second through posts 320 may be arranged in a plurality of rows (e.g., in the y direction). The second through posts 320 may be electrically connected to the second semiconductor chip 600 through the second redistribution substrate 400.

Left and right in the x direction may be relative concepts. Accordingly, positions of the first semiconductor chip 200, the first through posts 310, and the second through posts 320 may be changed. For example, the first semiconductor chip 200 may be biased to the left in the x direction, the first through posts 310 may be arranged on the right side of the first semiconductor chip 200 in the x direction, and the second through posts 320 may be arranged on the left side of the first semiconductor chip 200 in the x direction. For example, the first through posts 310 and the second through posts 320 may be disposed opposites sides of the first semiconductor chip 200 in a horizontal direction (e.g., the x direction). In addition, the second semiconductor chip 600 may be arranged on the left in the x direction to correspond to (e.g., to vertically overlap) the first semiconductor chip 200, and the semiconductor device 500 may be arranged on the right in the x direction.

The through posts 300 may include, for example, Cu. Accordingly, each of the through posts 300 may be referred to as a Cu-post. However, the material of the through posts 300 is not limited to Cu. The through posts 300 may be formed through electroplating using a seed metal. The seed metal may include one of various metal materials such as Cu, titanium (Ti), tantalum (Ta), titanium nitride (TiN), and tantalum nitride (TaN). In the semiconductor package 1000 of the current embodiment, the seed metal may be included as part of the through posts 300. For example, both the seed metal and the through posts 300 may include Cu. Accordingly, in FIG. 1B, the seed metal is not separately illustrated.

The second redistribution substrate 400 may be arranged on the first semiconductor chip 200, the through posts 300, and the first sealant 910. The second redistribution substrate 400 has a structure similar to that of the first redistribution substrate 100, but may differ in thickness. For example, the second redistribution substrate 400 may include a second body insulating layer 401 and a second redistribution line 410. For example, the second redistribution substrate 400 may include a second plurality of redistribution lines 410 spaced apart from each other in a vertical direction. However, the number of layers of the second redistribution lines 410 of the second redistribution substrate 400 may be less than the number of layers of the first redistribution lines 110 of the first redistribution substrate 100. However, in some embodiments, the number of layers of the second redistribution lines 410 of the second redistribution substrate 400 may be the same as or substantially the same as the number of layers of the first redistribution lines 110 of the first redistribution substrate 100. The second redistribution lines 410 of the second redistribution substrate 400 may be electrically connected to the external connection terminals 700 through the through posts 300 and the first redistribution lines 110 of the first redistribution substrate 100.

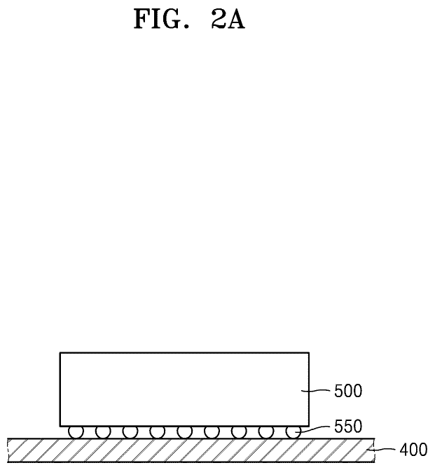

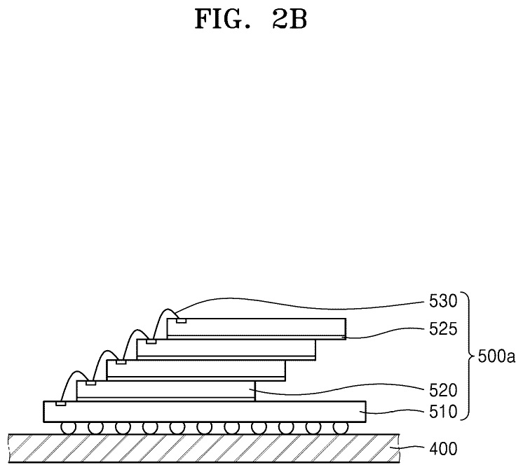

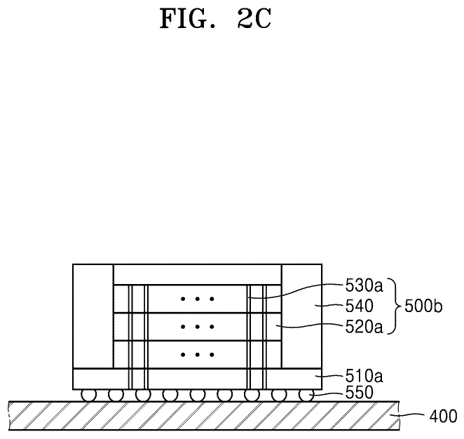

The semiconductor device 500 may be mounted on the second redistribution substrate 400 through third connection terminals 550. The semiconductor device 500 may be arranged on the left side of the second redistribution substrate 400 in the x direction to correspond to (e.g., to vertically overlap) the first through posts 310. The semiconductor device 500 may be a single chip or a package including a plurality of chips. For example, when the semiconductor device 500 is a single chip, the semiconductor device 500 may include or may be a memory chip. When the semiconductor device 500 is a package, the semiconductor device 500 may include, for example, a plurality of memory chips. Each memory chip of the semiconductor device 500 may include or may be, for example, a volatile memory device such as dynamic random access memory (DRAM) or SRAM, or a non-volatile memory device such as flash memory. In the semiconductor package 1000 of the current embodiment, each memory chip of the semiconductor device 500 may be, for example, a DRAM chip. The type of memory chip of the semiconductor device 500 is not limited to a DRAM chip. The single chip structure or package structure of the semiconductor device 500 is described in more detail in description with respect to FIGS. 2A to 2C.

When the semiconductor device 500 is a package, the semiconductor package 1000 of the current embodiment may correspond to or may have a package on package (POP) structure. For example, in the semiconductor package 1000 of the current embodiment, the first redistribution substrate 100, the first semiconductor chip 200, the through posts 300, and the second redistribution substrate 400 may constitute a lower package, and the semiconductor device 500 having the package structure may constitute an upper package. Accordingly, the semiconductor package 1000 of the current embodiment may have the POP structure in which the upper package is stacked on the lower package.

The second semiconductor chip 600 may be mounted on the second redistribution substrate 400 through the fourth connection terminals 650. The second semiconductor chip 600 may be arranged on the right side of the second redistribution substrate 400 in the x direction to correspond to (e.g., vertically overlap) the first semiconductor chip 200. As described above, because the second semiconductor chip 600 is arranged on the first semiconductor chip 200, a signal path between the first semiconductor chip 200 and the second semiconductor chip 600 may be minimized and heat dissipation characteristics may be maximized.

In some embodiments, the second semiconductor chip 600 may be mounted on the second redistribution substrate 400 through pad-to-pad bonding, hybrid bonding (HB), or bonding using an anisotropic conductive film (ACF). For reference, because the pads usually include Cu, pad-to-pad bonding is also called Cu-to-Cu bonding in certain embodiments. The HB may mean a combination of pad-to-pad bonding and insulator-to-insulator bonding. The ACF conducting electricity in only one direction may refer to a conductive film made by mixing fine conductive particles with an adhesive resin to form a film.

The second semiconductor chip 600 may be a logic chip. Accordingly, the second semiconductor chip 600 may include a plurality of logic elements therein. Here, the logic elements performing various signal processing may include, for example, an AND, an OR, a NOT, or a flip-flop. In the semiconductor package 1000 of the current embodiment, the second semiconductor chip 600 may be, for example, an application processor (AP) chip. The second semiconductor chip 600 may be a control chip, a processing chip, or a central processing unit (CPU) chip depending on a function of the second semiconductor chip 600. In terms of integrated functionality, the second semiconductor chip 600 may be a system on chip (SoC) together with or independently of the first semiconductor chip 200.

The second semiconductor chip 600 may include a substrate and an active layer. However, unlike the first semiconductor chip 200, the second semiconductor chip 600 may not include through electrodes. The active layer may include an integrated circuit layer and a multi-layer wiring structure. The integrated circuit layer may include a plurality of integrated devices. The multi-layer wiring structure may be arranged under the integrated circuit layer and may include multi-layered wiring lines. A bottom surface of the second semiconductor chip 600 may be a front side that is an active surface and a top surface of the second semiconductor chip 600 may be a back side that is an inactive surface. For example, a bottom surface of the active layer may correspond to the front side of the second semiconductor chip 600, and a top surface of the substrate may correspond to the back side of the second semiconductor chip 600.

The external connection terminals 700 may be electrically connected to the first redistribution lines 110 through the external connection pads arranged on a bottom surface of the first redistribution substrate 100. Accordingly, the external connection terminals 700 may be electrically connected to the first semiconductor chip 200 through the first redistribution lines 110 and the first connection terminals 250 of the first redistribution substrate 100. In addition, the external connection terminals 700 may electrically connect the semiconductor package 1000 to a package substrate of an external system or a main board of an electronic device such as a mobile device. The external connection terminal 700 may include at least one of conductive materials, for example, solder, tin (Sn), silver (Ag), Cu, and aluminum (Al). However, the material of the external connection terminal 700 is not limited to the above-described materials.

The external connection terminals 700 may be arranged on a first bottom surface of the first redistribution substrate 100 corresponding to (e.g., vertically overlapping) a bottom surface of the first semiconductor chip 200 and a second bottom surface of the first redistribution substrate 100 extending outward in the x and y directions from the first bottom surface (e.g., portions of the bottom surface of the first redistribution substrate 100 vertically not overlapping the bottom surface of the first semiconductor chip 200). As such, a package structure in which the external connection terminals 700 are arranged in a wider region than the bottom surface of the first semiconductor chip 200 is referred to as a fan-out (FO) package structure. A package structure in which the external connection terminals 700 are arranged only on the first bottom surface corresponding to (e.g., vertically overlapping) the bottom surface of the first semiconductor chip 200 is referred to as a fan-in (FI) package structure.

A passive element 800 may be arranged on the bottom surface of the first redistribution substrate 100. According to an embodiment, the passive element 800 may be arranged on a top surface of the first redistribution substrate 100 or in the first redistribution substrate 100. In certain embodiments, the passive element 800 may be arranged on a bottom or top surface of the second redistribution substrate 400 or in the second redistribution substrate 400. The passive element 800 may include a two-terminal element such as a resistor, an inductor, or a capacitor. In the semiconductor package 1000 of the current embodiment, the passive element 800 may include a multi-layer ceramic capacitor (MLCC) 810 and an Si-capacitor 820.

The sealant 900 may include a first sealant 910 and a second sealant 920. The first sealant 910 may be arranged between the first redistribution substrate 100 and the second redistribution substrate 400. The first sealant 910 may cover (e.g., contact) and seal side surfaces of the through posts 300 and side and top surfaces of the first semiconductor chip 200. In some embodiments, the first semiconductor chip 200 may be connected to the second redistribution substrate 400 by pad-to-pad bonding, HB, or bonding using an ACF, and the first sealant 910 may not be arranged between the first semiconductor chip 200 and the second redistribution substrate 400.

The second sealant 920 may be arranged on the second redistribution substrate 400 and may cover (e.g., contact) and seal side surfaces of the semiconductor device 500 and the second semiconductor chip 600. The second sealant 920 may fill a space between the second redistribution substrate 400 and the semiconductor device 500 and spaces among/between the third connection terminals 550. In addition, the second sealant 920 may fill a space between the second redistribution substrate 400 and the second semiconductor chip 600 and spaces among/between the fourth connection terminals 650.

However, in some embodiments, an underfill may be filled between the semiconductor device 500 and the second redistribution substrate 400 and among/between the third connection terminals 550, and side surfaces of the underfill may be covered with (e.g., contact) the second sealant 920. In some embodiments, an underfill may be filled between the second semiconductor chip 600 and the second redistribution substrate 400 and among/between the fourth connection terminals 650, and side surfaces of the underfill may be covered with (e.g., contact) the second sealant 920.

The second sealant 920 may seal the semiconductor device 500 and the second semiconductor chip 600 to expose top surfaces of the semiconductor device 500 and the second semiconductor chip 600. For example, as illustrated in FIG. 1B, top surfaces of the semiconductor device 500, the second semiconductor chip 600 and the second sealant 920 may be substantially coplanar. Because the second semiconductor chip 600 is exposed from the second sealant 920, heat dissipation characteristics of the second semiconductor chip 600 may be maximized. Because the second sealant 920 exposes the top surfaces of the semiconductor device 500 and the second semiconductor chip 600, a thickness of the second sealant 920 may be minimized and the total thickness of the semiconductor package 1000 may be reduced.

In the semiconductor package 1000 of the current embodiment, for example, the first semiconductor chip 200 may have a thickness of 0.2 mm or less, the second semiconductor chip 600 may have a thickness of 0.5 mm or less, and the total thickness of the semiconductor package 1000 may be 1.0 mm or less. In terms of an area of the semiconductor package 1000 of the current embodiment, for example in a plan view, the first semiconductor chip 200 may have a size of 13.0*11.0 mm² or less, the second semiconductor chip 600 may have a size of 12*10 mm² or less, the semiconductor device 500 may have a size of 7.0*12.5 mm² or less, and the total area of the package may be 17.0*14.0 mm² or less. However, thicknesses and areas of the components of the semiconductor package 1000 of the current embodiment are not limited to the above values.

The sealant 900 may include an insulating material, for example, a thermosetting resin such as an epoxy resin, a thermoplastic resin such as polyimide, or a resin including a reinforcing material such as an inorganic filler. For example, the sealant 900 may include ABF, FR-4, or BT resin. In some embodiments, the sealant 900 may include a molding material such as an epoxy molding compound (EMC) or a photosensitive material such as a photo-imagable encapsulant (PIE). However, the material of the sealant 900 is not limited to the above-described materials.

Briefly looking at a relationship between the planar sizes and positions of the first and second redistribution substrates 100 and 400, the first and second semiconductor chips 200 and 600, and the semiconductor device 500 with reference to FIG. 1A, the first and second redistribution substrates 100 and 400 may have substantially the same size as the sealant 900 in a plan view. Accordingly, the first semiconductor chip 200 and the through posts 300 may be positioned in the first redistribution substrate 100 in a plan view. In addition, the semiconductor device 500 and the second semiconductor chip 600 arranged on the through posts 300 and the first semiconductor chip 200 may also be positioned in the second redistribution substrate 400 in a plan view.

Most of the first semiconductor chip 200 may vertically overlap the second semiconductor chip 600, and only part of the first semiconductor chip 200 may vertically overlap the semiconductor device 500. For example, the semiconductor device 500 may vertically overlap the first through posts 310 and the left portion of the first semiconductor chip 200 in the x direction. The second semiconductor chip 600 may vertically overlap the second through posts 320 and the central and right portions of the first semiconductor chip 200 in the x direction.

The semiconductor package 1000 of the current embodiment may simultaneously maximize heat dissipation characteristics and implement a small form factor by using a fan-out wafer-level package (FOWLP) structure. For example, the first semiconductor chip 200 may be electrically connected to the second redistribution substrate 400 through the through electrodes 220 and the second connection terminals 270 and may have a large thickness corresponding to the first sealant 910. Accordingly, heat generated by the first semiconductor chip 200 may be effectively transmitted to the second redistribution substrate 400. In addition, the second semiconductor chip 600 may be arranged on the second redistribution substrate 400 with a top surface exposed and may have a large thickness corresponding to the second sealant 920. Accordingly, heat generated by the second semiconductor chip 600 may be effectively dissipated, and heat generated by the first semiconductor chip 200 may also be dissipated upward from the semiconductor package 1000 together with the second redistribution substrate 400. For example, the heat generated from the first semiconductor chip 200 may be dissipated upward through the second redistribution substrate 400 and the second semiconductor chip 600. As a result, heat dissipation characteristics of the semiconductor package 1000 may be significantly improved.

In addition, in the semiconductor package 1000 of the current embodiment, as illustrated in FIGS. 1A and 1B, the first semiconductor chip 200 and the second semiconductor chip 600 may be vertically stacked through the second redistribution substrate 400. Accordingly, the semiconductor package 1000 of the current embodiment may implement the small form factor. Furthermore, because the second through posts 320 are arranged under the second semiconductor chip 600, power may be effectively transmitted to the second semiconductor chip 600 through the second through posts 320. For example, a power path to the second semiconductor chip 600 may have the shortest distance by using the second through posts 320 and the second redistribution substrate 400. In the semiconductor package 1000 of the current embodiment, it is not necessary to separately make the first semiconductor chip 200 and the second semiconductor chip 600 in a 3D-IC structure. Accordingly, the semiconductor package 1000 of the current embodiment may benefit from turn around time (TAT) and may be greatly advantageous in terms of throughput and investment/manufacturing cost efficiency. For example, the semiconductor package 1000 of the present embodiment may increase data transfer rate and reduce manufacturing cost of the semiconductor package 1000 comparing to comparative examples.

For reference, a structure in which the first semiconductor chip 200 and the second semiconductor chip 600 have the 3D-IC structure applied to a semiconductor package is considered. Here, the 3D-IC structure may be a structure in which the second semiconductor chip 600 is directly stacked on the first semiconductor chip 200 through connection terminals and is integrated with the first semiconductor chip 200. In the case of a semiconductor package structure in which the 3D-IC structure is arranged between a lower redistribution substrate and an upper redistribution substrate, a small form factor may be implemented, but there are limitations in heat dissipation characteristics. In addition, to improve heat dissipation characteristics, a heat path block HPB such as a heat sink may be added to the upper redistribution substrate, and accordingly, the total thickness of the semiconductor package may be increased. In the case of a semiconductor package structure in which the upper redistribution substrate is omitted and a semiconductor device including a memory chip and a 3D-IC are arranged together on one redistribution substrate, the heat dissipation characteristics may be maximized, but as the 3D-IC is arranged side-by-side next to the semiconductor device, there may be limitations in implementing the small form factor.

As described above, the semiconductor package 1000 of the current embodiment may have the FOWLP structure and may simultaneously maximize heat dissipation characteristics and implement the small form factor. In addition, the semiconductor package 1000 of the current embodiment may be advantageous compared to the package structure including the 3D-IC structure in terms of power supply to the second semiconductor chip 600, TAT gain, data throughput, and investment/manufacturing cost.

FIGS. 2A to 2C are cross-sectional views illustrating a structure of a memory device in more detail in the semiconductor package 1000 of FIG. 1B.

Referring to FIG. 2A, a semiconductor device 500 may include or may be a memory chip. The memory chip may include, for example, a volatile memory device such as DRAM or SRAM, or a non-volatile memory device such as flash memory. In the semiconductor package 1000 of the current embodiment, the memory chip of the semiconductor device 500 may include or may be, for example, a DRAM chip. The semiconductor device 500 may be mounted on the second redistribution substrate 400 in a flip-chip bonding structure using the third connection terminals 550. Each of the third connection terminals 550 may include a pillar and solder, or may include only solder.

Referring to FIG. 2B, a semiconductor device 500a may include or may be a semiconductor package having a wire bonding structure. For example, the semiconductor device 500a may include a package substrate 510 and a plurality of memory chips 520 stacked on the package substrate 510. The plurality of memory chips 520 may be mounted on the package substrate 510 in a wire bonding structure using adhesive layers 525 and wires 530. For example, each of the memory chips 520 may be electrically connected to another memory chip 520 and/or to the package substrate 510 by one or more conductive wires. Each memory chip 520 of the semiconductor device 500a may include or may be, for example, a volatile memory device such as DRAM or SRAM, or a non-volatile memory device such as flash memory. In the semiconductor package 1000 of the current embodiment, the memory chip 520 of the semiconductor device 500a may include, for example, a DRAM chip. The semiconductor device 500a may include an internal sealant sealing the plurality of memory chips 520 and the wires 530 on the package substrate 510. However, in FIG. 2B, for convenience, the internal sealant is omitted.

In FIG. 2B, although four memory chips 520 are stacked on the package substrate 510, the number of memory chips 520 is not limited to four. For example, three or less or five or more memory chips 520 may be stacked on the package substrate 510. In addition, a stack or arrangement of the memory chips 520 is not limited to a staircase structure and may be stacked on the package substrate 510 in a zigzag structure or a combination of the staircase structure and the zigzag structure. For example, the zigzag structure may be a stack structure in which the memory chips 520 are vertically stacked and alternately shifted in two opposite horizontal directions by a predetermined distance from respective immediately below memory chips 520. The semiconductor device 500a having a package structure may also be mounted on the second redistribution substrate 400 through the third connection terminals 550.

Referring to FIG. 2C, a semiconductor device 500b may include or may be a high bandwidth memory (HBM) package. For example, the semiconductor device 500b may include a base chip 510a, a plurality of core chips 520a stacked on the base chip 510a, and an internal sealant 540. In addition, the base chip 510a and the plurality of core chips 520a may include through electrodes 530a therein. The uppermost core chip 520a among the plurality of core chips 520a may not include the through electrodes 530a.

The base chip 510a may include logic elements. Accordingly, the base chip 510a may be a logic chip. The base chip 510a may be arranged under the core chips 520a, may integrate signals received from the core chips 520a and transmit the integrated signal to the outside, and may transmit signals and power from the outside to the core chips 520a. Accordingly, the base chip 510a may be a buffer chip or a control chip. Each of the plurality of core chips 520a may be a memory chip. For example, each of the plurality of core chips 520a may be a DRAM chip. Each of the core chips 520a may be stacked on the base chip 510a or a lower core chip 520a through pad-to-pad bonding, HB, bonding using connection terminals, or bonding using an ACF. In FIG. 2C, although four core chips 520a are stacked on the base chip 510a, the number of core chips 520a is not limited to four. For example, three or less or five or more core chips 520a may be stacked on the base chip 510a.

The third connection terminals 550 may be arranged on a bottom surface of the base chip 510a. Accordingly, the semiconductor device 500b of the HBM package may also be mounted on the second redistribution substrate 400 through the third connection terminals 550. The plurality of core chips 520a on the base chip 510a may be sealed by the internal sealant 540. However, a top surface of the uppermost core chip 520a among the plurality of core chips 520a may not be covered with the internal sealant 540. In other embodiments, however, the top surface of the uppermost core chip 520a may be covered with (e.g., contact) the internal sealant 540.

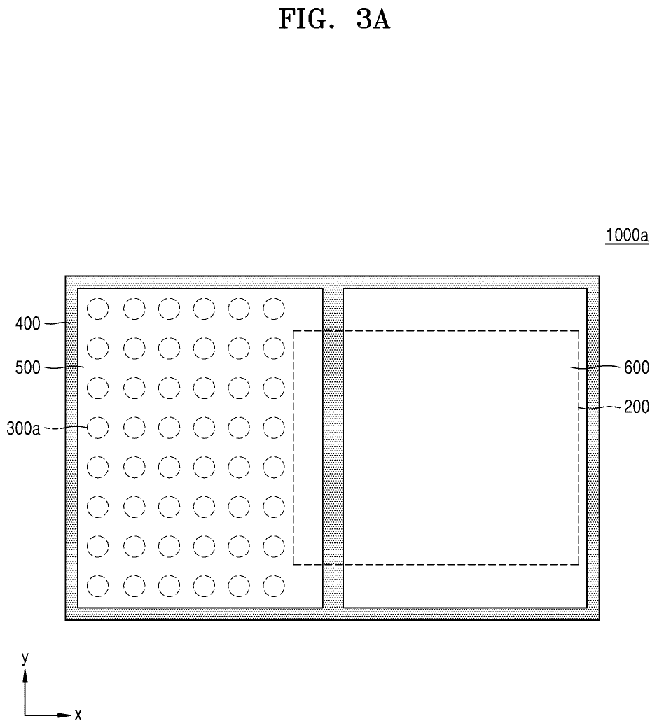

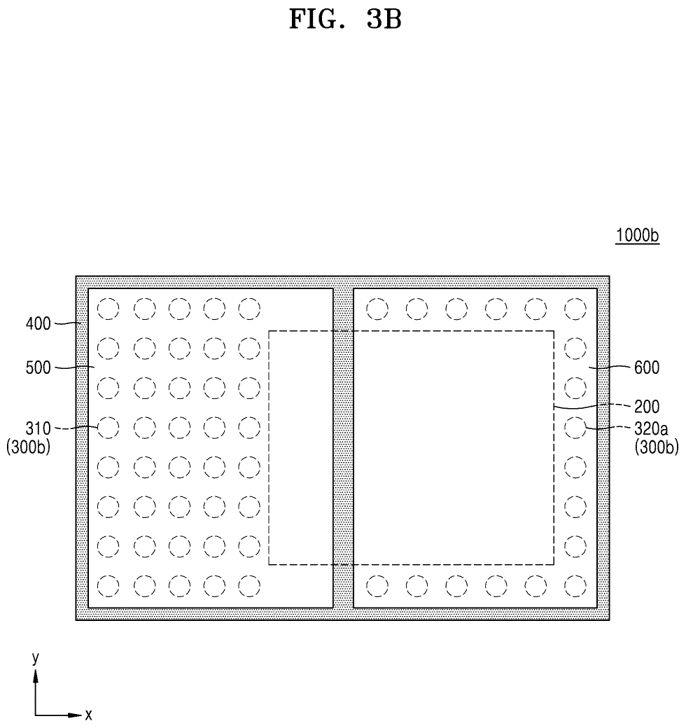

FIGS. 3A and 3B are plan views of semiconductor packages 1000a and 1000b according to embodiments, and each may correspond to the plan view of FIG. 1A. Description previously given with reference to FIGS. 1A to 2C may be applied to the present embodiment, and will be simply given or omitted in the below description for simplicity of description.

Referring to FIG. 3A, the semiconductor package 1000a of the current embodiment may be different from the semiconductor package 1000 of FIG. 1A in an arrangement of through posts 300a. For example, the semiconductor package 1000a of the current embodiment may include a first redistribution substrate 100, a first semiconductor chip 200, the through posts 300a, a second redistribution substrate 400, a semiconductor device 500, a second semiconductor chip 600, external connection terminals 700, a passive element 800, and a sealant 900. Description given to the first redistribution substrate 100, the first semiconductor chip 200, the second redistribution substrate 400, the semiconductor device 500, the second semiconductor chip 600, the external connection terminals 700, the passive element 800, and the sealant 900 is the same as the description of those of the semiconductor package 1000 of FIG. 1A.

In the semiconductor package 1000a of the current embodiment, the through posts 300a may be arranged only on the left side of the first semiconductor chip 200 in the x direction on the first redistribution substrate 100. For example, the through posts 300a may not be arranged on the first redistribution substrate 100 on the right side of the first semiconductor chip 200 in the x direction. Accordingly, the first semiconductor chip 200 may be arranged on the first redistribution substrate 100 to be more biased/shifted to the right in the x direction. As a result, an area in which the first semiconductor chip 200 vertically overlaps the second semiconductor chip 600 may increase, and heat dissipation efficiency of the first semiconductor chip 200 may be improved.

Referring to FIG. 3B, the semiconductor package 1000b of the current embodiment may be different from the semiconductor package 1000 of FIG. 1A in an arrangement of through posts 300b. For example, the semiconductor package 1000b of the current embodiment may include a first redistribution substrate 100, a first semiconductor chip 200, the through posts 300b, a second redistribution substrate 400, a semiconductor device 500, a second semiconductor chip 600, external connection terminals 700, a passive element 800, and a sealant 900. Description of the first redistribution substrate 100, the first semiconductor chip 200, the second redistribution substrate 400, the semiconductor device 500, the second semiconductor chip 600, the external connection terminals 700, the passive element 800, and the sealant 900 is the same as the description of those of the semiconductor package 1000 of FIG. 1A.

In the semiconductor package 1000b of the current embodiment, the through posts 300b may include first through posts 310 and second through posts 320a. The first through posts 310 may be arranged on the first redistribution substrate 100 on the left side of the first semiconductor chip 200 in the x direction. The second through posts 320a may be arranged on the first redistribution substrate 100 on the right side of the first semiconductor chip 200 in the x direction and on both sides of the first semiconductor chip 200 in the y direction. For example, the second through posts 320a may be arranged to surround the first semiconductor chip 200 on the right side of the first semiconductor chip 200 in the x direction and on both sides of the first semiconductor chip 200 in the y direction. For example, the second through posts 320a may be arranged in a row to surround three side surfaces of the first semiconductor chip 200. However, in some embodiments, the second through posts 320a may be arranged in a plurality of rows on each of the three side surfaces to surround the three side surfaces of the first semiconductor chip 200.

In the semiconductor package 1000b of the current embodiment, more second through posts 320a may be arranged under the second redistribution substrate 400 corresponding to the second semiconductor chip 600. Accordingly, as a power supply path to the second semiconductor chip 600 increases, the effect of power transmission to the second semiconductor chip 600 may be further improved.

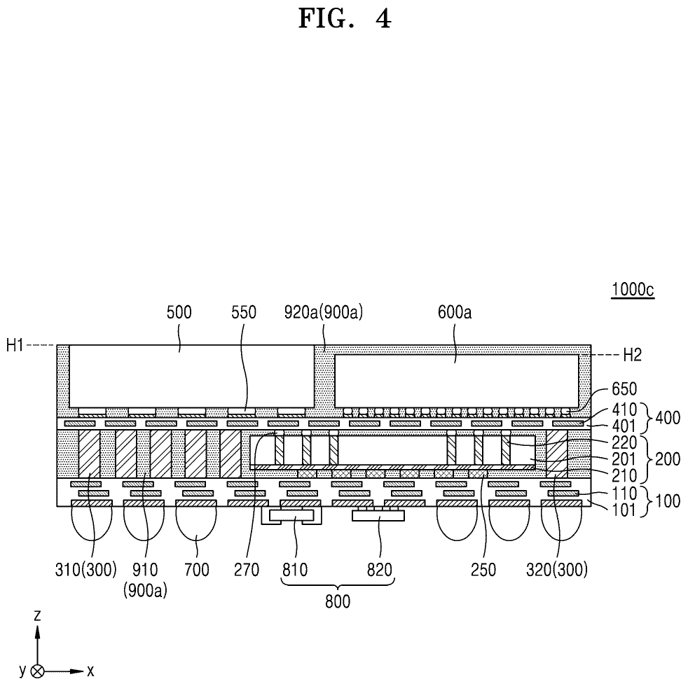

FIG. 4 is a cross-sectional view of a semiconductor package according to an embodiment, and may correspond to the cross-sectional view of FIG. 1B. Description previously given with reference to FIGS. 1A to 3B may also be applied to the present embodiment, and will be simply given or omitted in the below description for simplicity of description.

Referring to FIG. 4, the semiconductor package 1000c of the current embodiment may be different from the semiconductor package 1000 of FIG. 1B in structures of a second semiconductor chip 600a and a sealant 900a. For example, the semiconductor package 1000c of the current embodiment may include a first redistribution substrate 100, a first semiconductor chip 200, through posts 300, a second redistribution substrate 400, a semiconductor device 500, the second semiconductor chip 600a, external connection terminals 700, a passive element 800, and the sealant 900a. Description of the first redistribution substrate 100, the first semiconductor chip 200, the second redistribution substrate 400, the semiconductor device 500, the external connection terminals 700, and the passive element 800 is the same as the description of those of the semiconductor package 1000 of FIG. 1A.

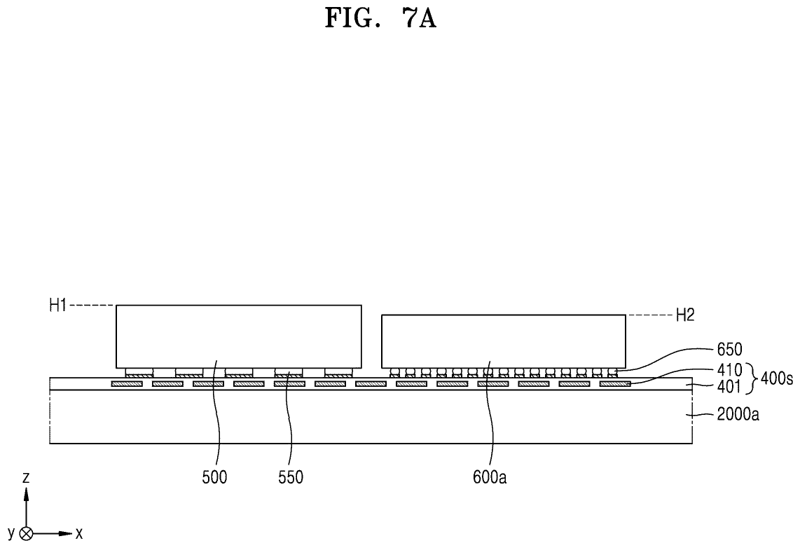

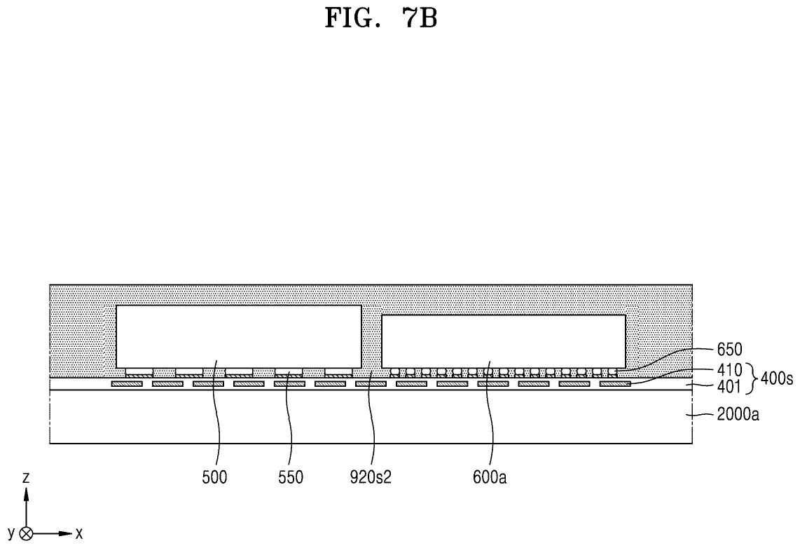

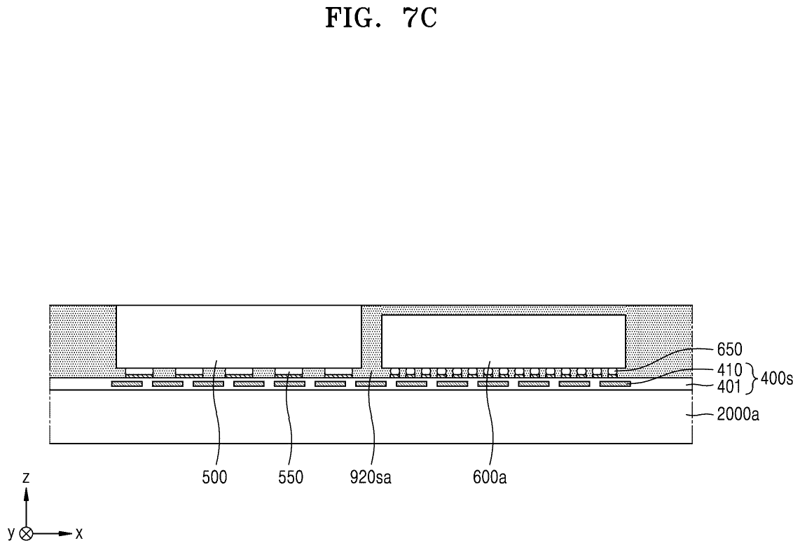

In the semiconductor package 1000c of the current embodiment, a thickness of the second semiconductor chip 600a may be less than a thickness of the second semiconductor chip 600 of the semiconductor package 1000 of FIG. 1B. Accordingly, a second height H2 that is a height of a top surface of the second semiconductor chip 600a mounted on the second redistribution substrate 400 may be less than a first height H1 that is a height of a top surface of the semiconductor device 500 mounted on the second redistribution substrate 400. As the top surface of the second semiconductor chip 600a is lower than the top surface of the semiconductor device 500, the sealant 900a may cover (e.g., contact) the top surface of the second semiconductor chip 600a. For example, a second sealant 920a may expose the top surface of the semiconductor device 500 and may not expose the top surface of the second semiconductor chip 600a. For reference, it may be advantageous in terms of heat dissipation characteristics for the top surface of the second semiconductor chip 600a to be exposed from the sealant 900a. However, when the semiconductor device 500 has a package structure, the second semiconductor chip 600a as a chip may be thinner than the semiconductor device 500 (e.g., as a package). Therefore, the semiconductor package 1000c of the current embodiment may be implemented in manufacturing processes in certain embodiments to accommodate a chip and a package. A method of manufacturing the semiconductor package 1000c according to the current embodiment is described in more detail with reference to FIGS. 7A to 7C.

The structures of several semiconductor packages 1000 and 1000a to 1000c have been described so far, but the inventive concept is not limited to the structures of the semiconductor packages described above. For example, the inventive concept may be applied to all semiconductor package structures having a 3D stacked structure of FOWLP, and may also be applied to all semiconductor package structures requiring a redistribution layer (RDL) process.

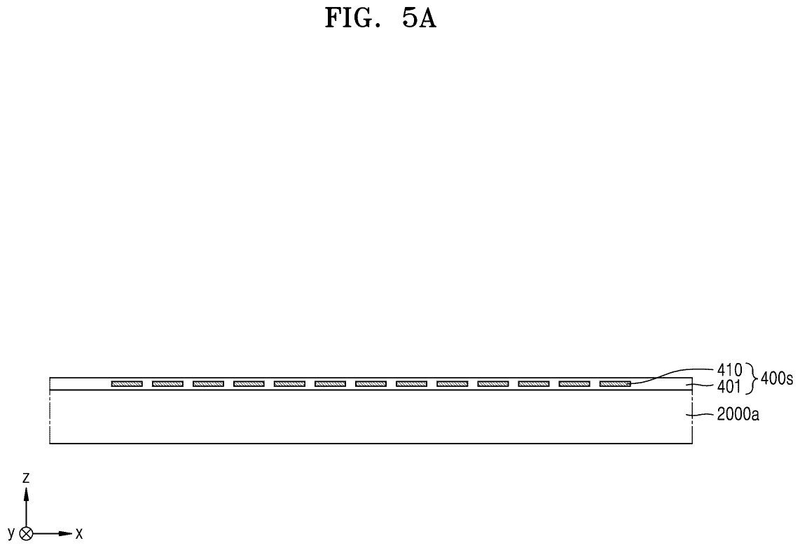

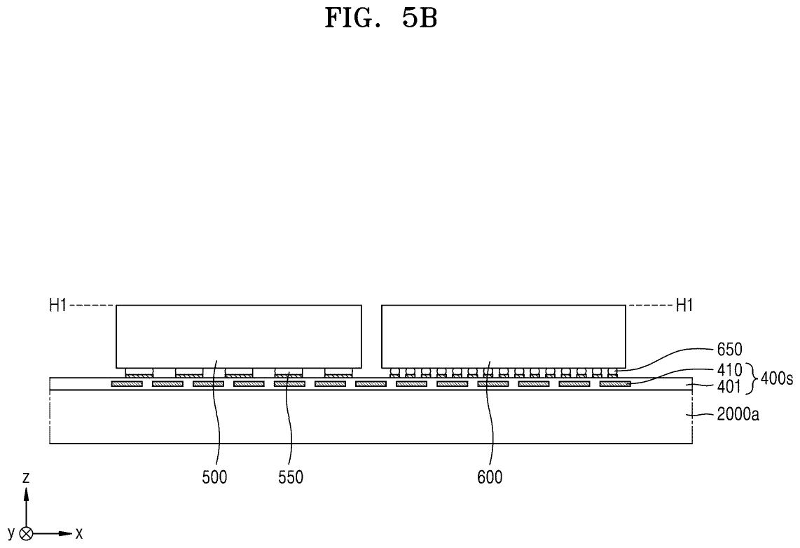

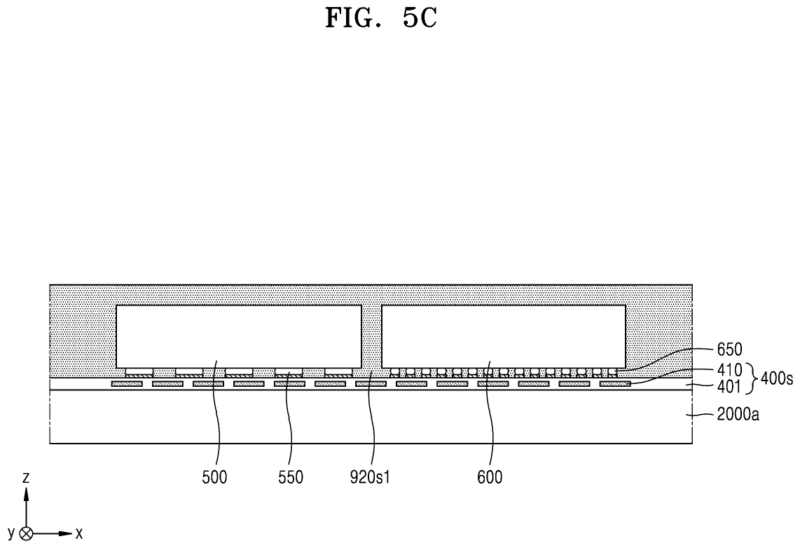

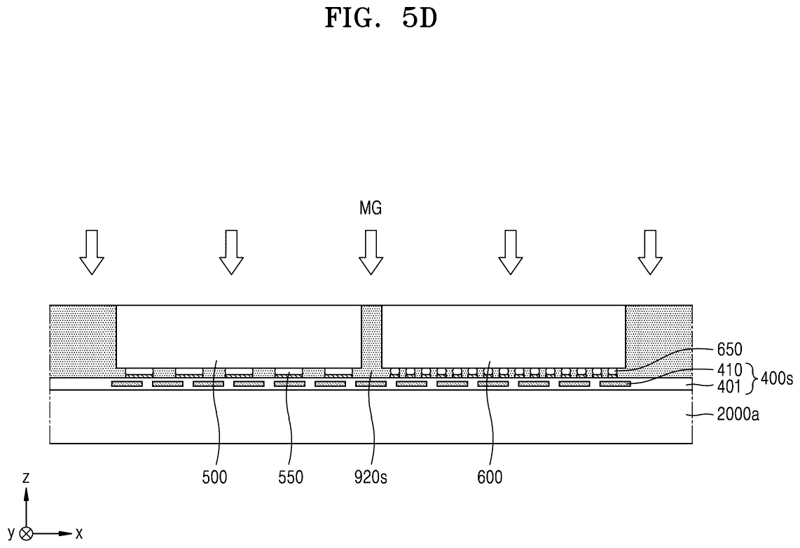

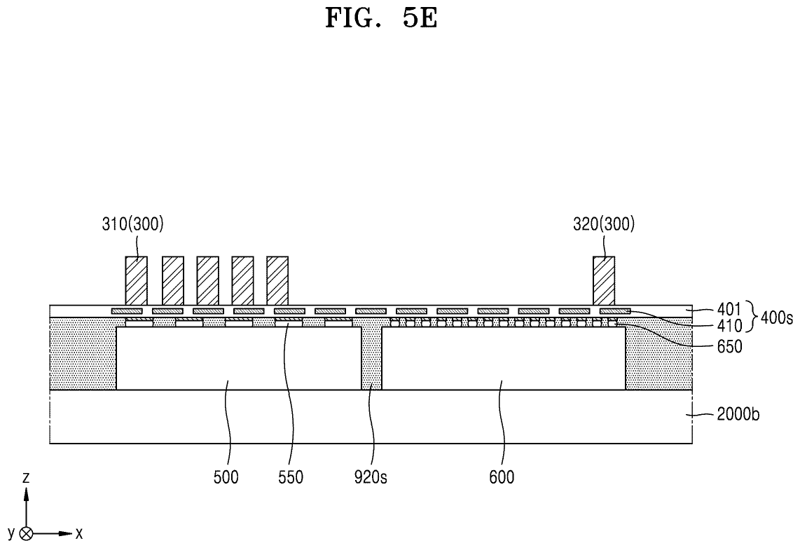

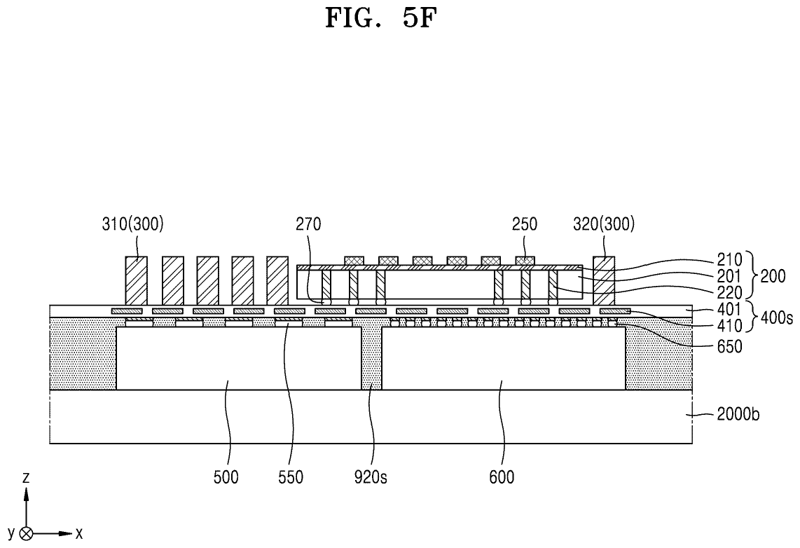

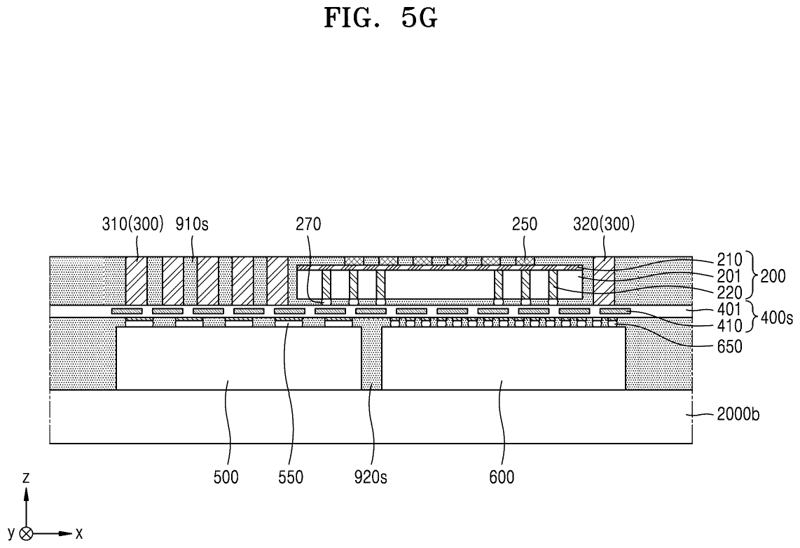

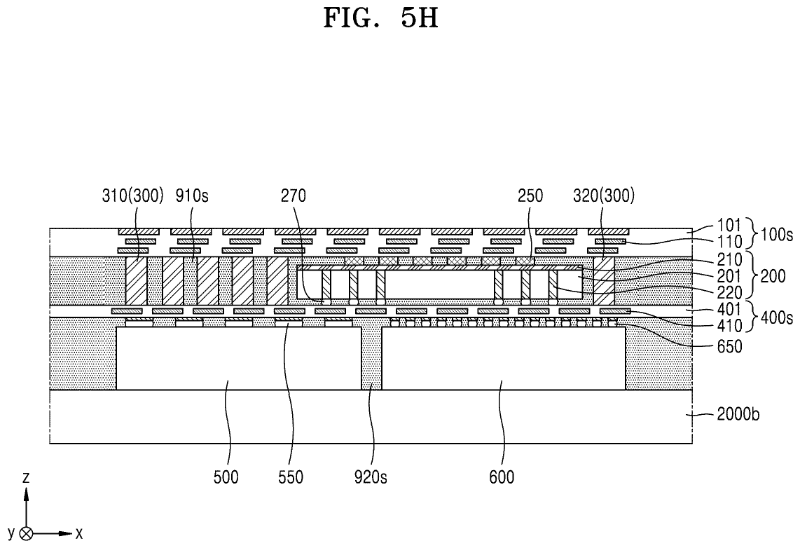

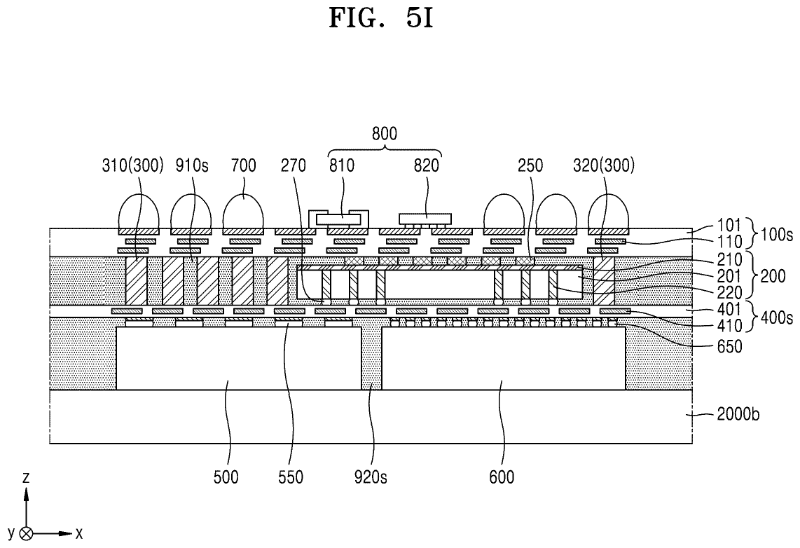

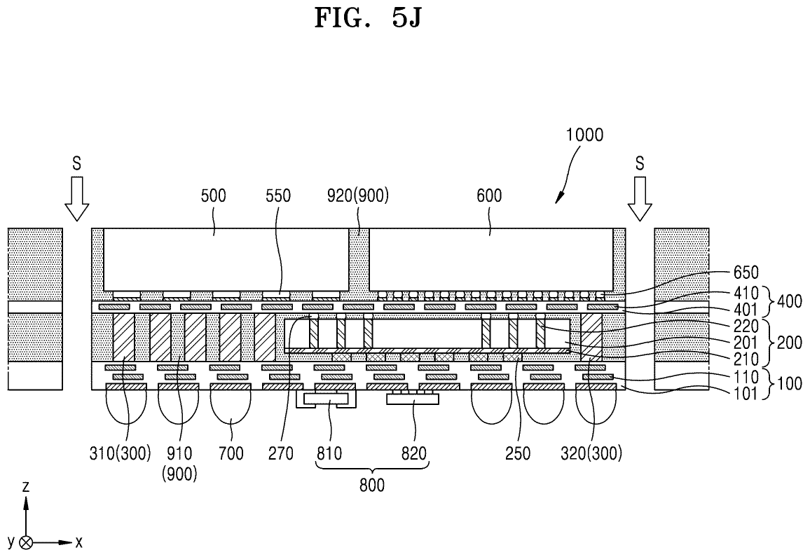

FIGS. 5A to 5J are cross-sectional views schematically illustrating processes of a method of manufacturing a semiconductor package according to an embodiment. Description of the method illustrated in FIGS. 5A to 5J will be given with reference to FIGS. 1A and 1B together, and the description previously given with reference to FIGS. 1A to 4 may also be applied to the present embodiment, and will be simply given or omitted in the below description for simplicity of description.

Referring to FIG. 5A, in the semiconductor package manufacturing method of the current embodiment, first, an upper redistribution substrate 400s is formed. The upper redistribution substrate 400s may include a second body insulating layer 401 and a second redistribution line 410. The upper redistribution substrate 400s may be formed on a first carrier substrate 2000a. The first carrier substrate 2000a may be a large-sized substrate such as a wafer. In addition, the upper redistribution substrate 400s formed on the first carrier substrate 2000a may be a large-sized redistribution substrate including a plurality of second redistribution substrates 400. Although not shown, an adhesive layer may be arranged between the upper redistribution substrate 400s and the first carrier substrate 2000a. The adhesive layer may adhere and fix the upper redistribution substrate 400s onto the first carrier substrate 2000a.

For reference, after subsequent components are formed on a large-sized redistribution substrate, a semiconductor package individualized through a sawing (S) process or singulation process is called a wafer level package (WLP). For example, the packaging process may be performed at a wafer level and then packages may be singulated by the sawing process. However, for convenience, only components corresponding to one second redistribution substrate 400 are illustrated in FIG. 5A and the following drawings.

Referring to FIG. 5B, after forming the upper redistribution substrate 400s, a semiconductor device 500 and a second semiconductor chip 600 are mounted on a first surface of the upper redistribution substrate 400s. Here, the first surface may correspond to the top surface of the second redistribution substrate 400 in the semiconductor package 1000 of FIG. 1B. For example, the semiconductor device 500 may be mounted on the first surface of the upper redistribution substrate 400s through third connection terminals 550, and the second semiconductor chip 600 may be mounted on the first surface of the upper redistribution substrate 400s through fourth connection terminals 650 to be adjacent to (e.g., side by side with) the semiconductor device 500 in the x direction. Various bonding processes such as reflow, thermal compression bonding (TCB), and laser assisted bonding (LAB) may be used for mounting the semiconductor device 500 by using the third connection terminals 550 and mounting the second semiconductor chip 600 by using the fourth connection terminals 650. The semiconductor device 500 and the second semiconductor chip 600 are the same as those described with reference to FIGS. 1A to 2C.

As illustrated in FIG. 5B, heights of top surfaces of the semiconductor device 500 and the second semiconductor chip 600 mounted on the first surface of the upper redistribution substrate 400s are substantially the same, and each of the top surfaces of the semiconductor device 500 and the second semiconductor chip 600 may have a first height H1. However, thicknesses of the semiconductor device 500 and the second semiconductor chip 600 may be the same or different. Accordingly, in order to make the heights of the top surfaces of the semiconductor device 500 and the second semiconductor chip 600 substantially the same, heights of the third connection terminals 550 and the fourth connection terminals 650 may be adjusted, e.g., to be the same or different from each other. In certain embodiments, in a subsequent grinding process for an upper sealant 920s1, an upper portion of either the semiconductor device 500 or the second semiconductor chip 600 may be removed.

Referring to FIG. 5C, after mounting the semiconductor device 500 and the second semiconductor chip 600 on the first surface of the upper redistribution substrate 400s, the semiconductor device 500 and the second semiconductor chip 600 are sealed with the upper sealant 920s1. The upper sealant 920s1 may cover/contact side and top surfaces of the semiconductor device 500 and the second semiconductor chip 600. In addition, the upper sealant 920s1 may fill a space between the upper redistribution substrate 400s and the semiconductor device 500, a space between the upper redistribution substrate 400s and the second semiconductor chip 600, spaces among/between the third connection terminals 550, and spaces among/between the fourth connection terminals 650. However, in some embodiments, an underfill is filled between the upper redistribution substrate 400s and the semiconductor device 500, and among/between the third connection terminals 550, and/or between the upper redistribution substrate 400s and the second semiconductor chip 600 and among/between the fourth connection terminals 650, and the upper sealant 920s1 may cover/contact side surfaces of the underfill. The material of the upper sealant 920s1 is the same as the material of the second sealant 920 described in the description of the semiconductor package 1000 of FIG. 1B.

Referring to FIG. 5D, thereafter, an upper portion of the upper sealant 920s1 is removed through a mold grinding (MG) process. After the MG process, the top surfaces of the semiconductor device 500 and the second semiconductor chip 600 may be exposed from the upper sealant 920s1. As the top surfaces of the semiconductor device 500 and the second semiconductor chip 600 are exposed through the MG process, top surfaces of the semiconductor device 500, the second semiconductor chip 600, and the upper sealant 920s1 may be substantially coplanar.

Referring to FIG. 5E, after the MG process, the upper redistribution substrate 400s and structures thereon are separated from the first carrier substrate 2000a, turned upside down, and attached to a second carrier substrate 2000b. For example, as illustrated in FIG. 5E, the semiconductor device 500, the second semiconductor chip 600, and the upper sealant 920s1 may be positioned at a lower portion and the upper redistribution substrate 400s may be positioned at an upper portion on the second carrier substrate 2000b. For example, the exposed top surfaces of the semiconductor device 500, the second semiconductor chip 600, and the upper sealant 920s1 may face downward and may be attached to a top surface of the second carrier substrate 2000b. Although not shown, an adhesive layer may be arranged between the exposed top surfaces of the semiconductor device 500, the second semiconductor chip 600, and the upper sealant 920s1 and the second carrier substrate 2000b.

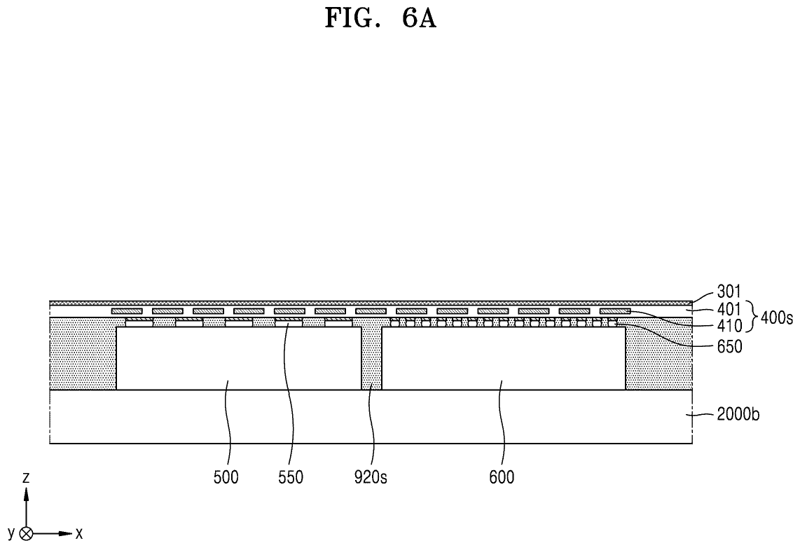

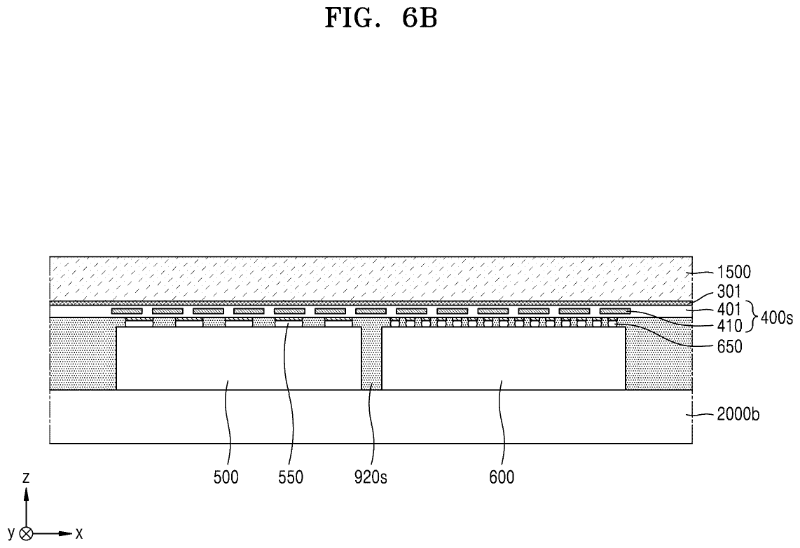

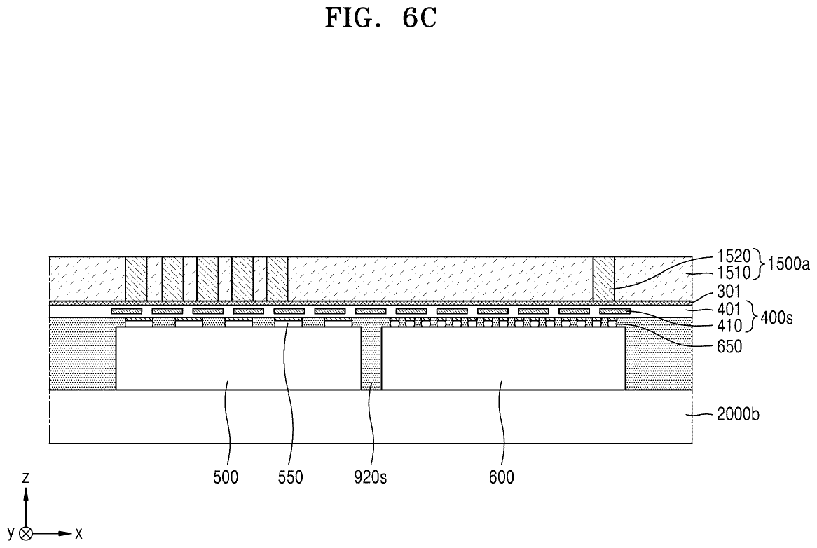

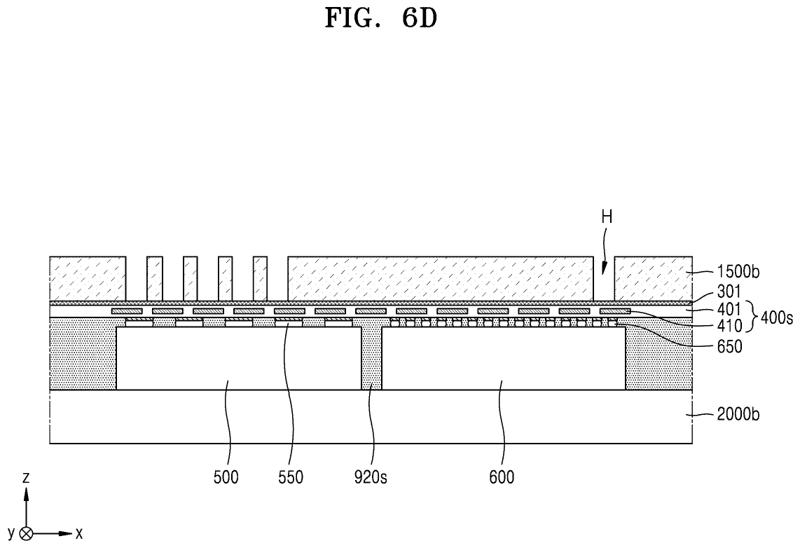

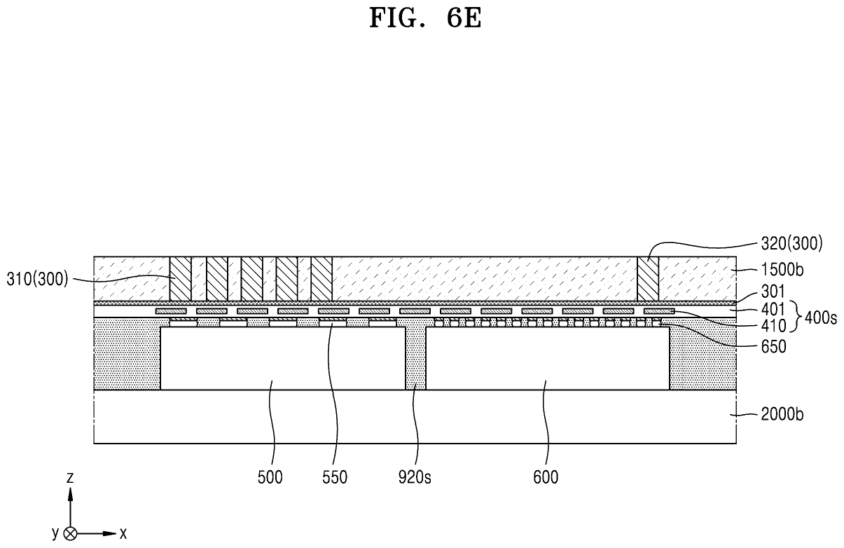

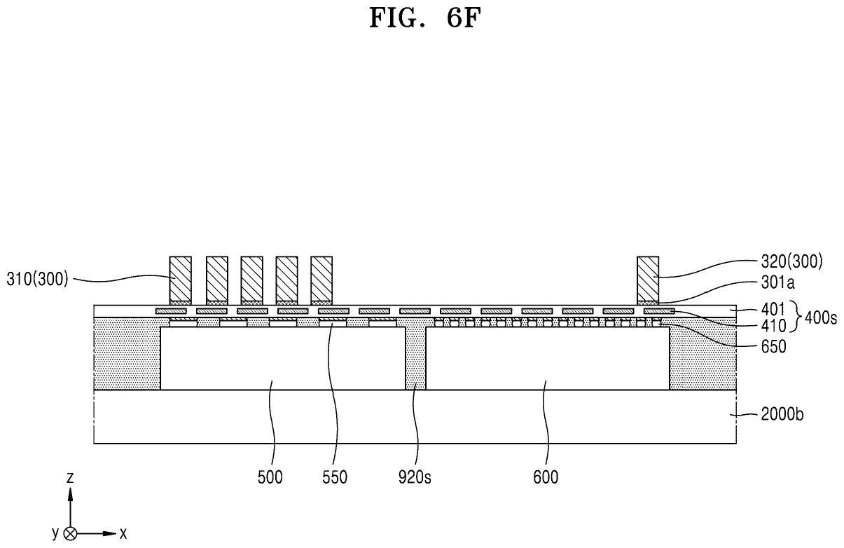

Thereafter, through posts 300 are formed on a second surface of the upper redistribution substrate 400s. Here, the second surface of the upper redistribution substrate 400s refers to an opposite surface of the first surface of the upper redistribution substrate 400s, and may correspond to a bottom surface of the second redistribution substrate 400 in the semiconductor package 1000 of FIG. 1B. The through posts 300 may include first through posts 310 and second through posts 320. The first through posts 310 may be arranged on the left side of the second surface of the upper redistribution substrate 400s in the x direction to correspond to (e.g., vertically overlap) the semiconductor device 500. The second through posts 320 may be arranged at the right side on the second surface of the upper redistribution substrate 400s in the x direction to correspond to (e.g., vertically overlap) the second semiconductor chip 600. A method of forming the through posts 300 is described in more detail with reference to FIGS. 6A to 6F.

Referring to FIG. 5F, after forming the through posts 300, the first semiconductor chip 200 is mounted on the second surface of the upper redistribution substrate 400s in a portion in which the through posts 300 are not arranged. For example, the first semiconductor chip 200 may be mounted on the second surface of the upper redistribution substrate 400s through the second connection terminals 270. The first connection terminals 250 may be arranged on a top surface of the first semiconductor chip 200. The first semiconductor chip 200 of the present embodiment is the same as the first semiconductor chip 200 described in the description of the semiconductor package 1000 of FIG. 1B.

Referring to FIG. 5G, after mounting the first semiconductor chip 200, a lower sealant 910s covering the through posts 300 and the first semiconductor chip 200 are formed on the second surface of the upper redistribution substrate 400s. The lower sealant 910s may cover/contact side and top surfaces of the through posts 300 and the first semiconductor chip 200. In addition, the lower sealant 910s may fill a space between the first semiconductor chip 200 and the upper redistribution substrate 400s, spaces among/between the second connection terminals 270, and spaces among/between the first connection terminals 250.

Thereafter, an upper portion of the lower sealant 910s is removed through an MG process. The top surfaces of the through posts 300 and the first connection terminals 250 of the first semiconductor chip 200 may be exposed from the lower sealant 910s through the MG process for the lower sealant 910s. The material of the lower sealant 910s is the same as the material of the first sealant 910 described in the description of the semiconductor package 1000 of FIG. 1B.

Referring to FIG. 5H, subsequently, a lower redistribution substrate 100s is formed on the first semiconductor chip 200, the through posts 300, and the lower sealant 910s. The lower redistribution substrate 100s may include a first body insulating layer 101 and a first redistribution line 110. The lower redistribution substrate 100s may include a plurality of first redistribution substrates 100.

Referring to FIG. 5I, after forming the lower redistribution substrate 100s, external connection terminals 700 and a passive element 800 are attached onto a first surface of the lower redistribution substrate 100s. The first surface of the lower redistribution substrate 100s may correspond to the bottom surface of the first redistribution substrate 100 in the semiconductor package 1000 of FIG. 1B. The external connection terminals 700 and the passive element 800 are the same as those described in the description of the semiconductor package 1000 of FIG. 1B.

Referring to FIG. 5J, after attaching the external connection terminals 700 and the passive element 800 onto the first surface of the lower redistribution substrate 100s, semiconductor packages included in the entire structure may be individualized through the sawing (S) process for the entire structure. The semiconductor package 1000 of FIG. 1B may be manufactured through individualization using the sawing (S) process. In addition, after the sawing (S) process, a sorting process may be performed to classify good products from defective products through electrical testing.

FIGS. 6A to 6F are cross-sectional views illustrating the process of FIG. 5E in more detail.

Referring to FIG. 6A, in the method of manufacturing a semiconductor package of the current embodiment, the through posts 300 may be formed on the second surface of the upper redistribution substrate 400s through the following process. First, a seed metal 301 is formed on the second surface of the upper redistribution substrate 400s. The seed metal 301 may be used in an electroplating process for forming the through posts 300 later. The seed metal 301 may include one of various metal materials, for example, Cu, Ti, Ta, TiN, and TaN. In the method of manufacturing a semiconductor package of the current embodiment, for example, the seed metal 301 may include Cu.

Referring to FIG. 6B, subsequently, photoresist (PR) 1500 is applied on the seed metal 301 of the upper redistribution substrate 400s. The PR 1500 may be applied, for example, through a spin coating method using a spin coater. The PR 1500 may be formed to have a thickness corresponding to (e.g., the same as) a length of the through post 300 in a vertical direction.

Referring to FIG. 6C, an exposure process is performed after the PR 1500 is applied. The exposure process may be performed by using a mask including a specific pattern. For example, light may be transmitted to a transparent portion of a transmissive mask to irradiate a predetermined portion of the PR 1500 with light. Chemical characteristics of the portion of the PR 1500 irradiated with light may be changed. For example, after the exposure process, the PR 1500 may be divided into an unexposed portion 1510 and an exposed portion 1520. As noted from FIG. 6C, the exposed portion 1520 may be positioned on the left and right sides of the upper redistribution substrate 400s in the x direction. The exposed portion 1520 on the left side may correspond to the first through posts 310, and the exposed portion 1520 on the right side may correspond to the second through posts 320. When the semiconductor packages 1000a and 1000b of FIGS. 3A and 3B are manufactured, a position of the exposed portion 1520 may vary depending on arrangement of the through posts 300a and 300b.

Referring to FIG. 6D, after the exposure process, a development process for the PR 1500 is performed. In the development process, for example, the exposed portion 1520 may be removed. For example, the PR 1500 may be a positive PR. According to an embodiment, a negative PR may be used. When the negative PR is used, a portion that is not exposed may be removed in the development process.

The exposed portion 1520 is removed through the development process to form a PR pattern 1500b. The PR pattern 1500b may include a plurality of through holes H. The seed metal 301 may be exposed at bottom surfaces of the plurality of through holes H. After the development process, by-products such as PR scum may remain in the plurality of through holes H. Accordingly, the by-products are removed through a cleaning process. For reference, the process of removing the PR scum is called a PR descum process. The PR descum process may be included in the cleaning process.

Referring to FIG. 6E, after the cleaning process, the through posts 300 are respectively formed in the plurality of through holes H through electroplating. The through posts 300 may include the first through posts 310 on the left side of the upper redistribution substrate 400s in the x direction and the second through posts 320 on the right side of the upper redistribution substrate 400s. The through posts 300 may include, for example, Cu. Although not shown, the through posts 300 may be formed on part of a top surface of the PR pattern 1500b adjacent to the plurality of through holes H beyond the plurality of through holes H.

Referring to FIG. 6F, the PR pattern 1500b is removed after the through posts 300 are formed. The PR pattern 1500b may be removed through an ashing/strip process. After the PR pattern 1500b is removed, the seed metal 301 may be exposed among/between the through posts 300. Subsequently, the seed metal 301 exposed among/between the through posts 300 is removed through an etching process. By removing the seed metal 301, the second surface of the upper redistribution substrate 400s may be exposed among/between the through posts 300. The seed metal 301 on bottom surfaces of the through posts 300 may be maintained. Because both the seed metal 301 and the through posts 300 include Cu, in FIGS. 5E to 5J, the seed metal 301 and the through posts 300 are illustrated as being integrated into the through posts 300.

FIGS. 7A to 7C are cross-sectional views schematically illustrating processes of a method of manufacturing a semiconductor package according to an embodiment. Description of the method illustrated in FIGS. 7A to 7C will be given with reference to FIG. 4 together, and the description previously given with reference to FIGS. 5A to 6F may also be applied to the present embodiment, and will be simply given or omitted.

Referring to FIG. 7A, in the semiconductor package manufacturing method of the current embodiment, first, the upper redistribution substrate 400s is formed on the first carrier substrate 2000a through the process of FIG. 5A. Thereafter, the semiconductor device 500 and the second semiconductor chip 600a are mounted on the first surface of the upper redistribution substrate 400s. For example, the semiconductor device 500 may be mounted on the first surface of the upper redistribution substrate 400s through the third connection terminals 550, and the second semiconductor chip 600a may be mounted on the first surface of the upper redistribution substrate 400s through the fourth connection terminals 650 to be adjacent to (e.g., to be side by side with) the semiconductor device 500.

The top surface of the semiconductor device 500 mounted on the first surface of the upper redistribution substrate 400s may have a first height H1, and the top surface of the second semiconductor chip 600a mounted on the first surface of the upper redistribution substrate 400s may have a second height H2. As illustrated in FIG. 7A, the second height H2 may be less than the first height H1. For example, the semiconductor device 500, the third connection terminals 550, and the fourth connection terminals 650 are the same as or substantially the same as the semiconductor device 500, the third connection terminals 550, and the fourth connection terminals 650 of the first semiconductor package 1000 and may have the same thickness or height accordingly. The second semiconductor chip 600a may have a thickness less than that of the second semiconductor chip 600 of the first semiconductor package 1000. Accordingly, the second height H2 of the top surface of the second semiconductor chip 600a may be less than the first height H1 of the top surface of the semiconductor device 500.

Referring to FIG. 7B, after mounting the semiconductor device 500 and the second semiconductor chip 600a on the first surface of the upper redistribution substrate 400s, the semiconductor device 500 and the second semiconductor chip 600a are sealed with the upper sealant 920s2. The upper sealant 920s2 may cover/contact side and top surfaces of the semiconductor device 500 and the second semiconductor chip 600a. In addition, the upper sealant 920s2 may fill a space between the upper redistribution substrate 400s and the semiconductor device 500, a space between the upper redistribution substrate 400s and the second semiconductor chip 600a, spaces among/between the third connection terminals 550, and spaces among/between the fourth connection terminals 650. However, in some embodiments, an underfill is filled between the upper redistribution substrate 400s and the semiconductor device 500 and among/between the third connection terminals 550, and/or between the upper redistribution substrate 400s and the second semiconductor chip 600a and among/between the fourth connection terminals 650 and the upper sealant 920s2 may cover/contact side surfaces of the underfill.

Referring to FIG. 7C, an upper portion of the upper sealant 920s2 is removed through an MG process. After the MG process, the top surface of the semiconductor device 500 may be exposed from the upper sealant 920sa. However, the top surface of the second semiconductor chip 600a may not be exposed and may be covered with (e.g., contact) the upper sealant 920sa. Thereafter, the semiconductor package 1000c of FIG. 4 may be manufactured through the processes of FIGS. 5E to 5J.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various changes in form and details may be made therein without departing from the spirit and scope of the following claims.

1. A semiconductor package comprising:
a first redistribution substrate;
a first semiconductor chip arranged on the first redistribution substrate on a right side in a first direction and including through electrodes;
first through posts arranged on the first redistribution substrate on a left side in the first direction on a side of the first semiconductor chip;
a second redistribution substrate arranged on the first semiconductor chip and first through posts;
a semiconductor device arranged on the second redistribution substrate on a left side in the first direction; and
a second semiconductor chip arranged on the second redistribution substrate on a right side in the first direction on a side of the semiconductor device.

2. The semiconductor package of claim 1, wherein the first semiconductor chip is electrically connected to the first redistribution substrate through first connection terminals arranged on a bottom surface of the first semiconductor chip, and is electrically connected to the second redistribution substrate through second connection terminals arranged on a top surface of the first semiconductor chip.

3. The semiconductor package of claim 2, wherein the first semiconductor chip is electrically connected to the second semiconductor chip through the second redistribution substrate and the second connection terminals.

4. The semiconductor package of claim 1, wherein the semiconductor device vertically overlaps the first through posts and a left portion of the first semiconductor chip in the first direction, and
wherein the second semiconductor chip vertically overlaps central and right portions of the first semiconductor chip in the first direction.

5. The semiconductor package of claim 4, further comprising second through posts arranged on the first redistribution substrate in at least one of a right side of the first semiconductor chip in the first direction and both sides of the first semiconductor chip in a second direction perpendicular to the first direction,
wherein the first through posts and the second through posts electrically connect the first redistribution substrate and the second redistribution substrate to each other.

6. The semiconductor package of claim 5, wherein the second through posts and the second redistribution substrate constitute a power path to the second semiconductor chip.

7. The semiconductor package of claim 1, further comprising:
a first sealant arranged between the first redistribution substrate and the second redistribution substrate and sealing the first semiconductor chip; and
a second sealant arranged on the second redistribution substrate and sealing the semiconductor device and the second semiconductor chip.

8. The semiconductor package of claim 7, wherein a top surface of the second semiconductor chip is exposed from the second sealant.

9. The semiconductor package of claim 7, wherein top surfaces of the semiconductor device, the second semiconductor chip, and the second sealant are coplanar.

10. The semiconductor package of claim 1, wherein the semiconductor device is a memory chip or a memory package, and
wherein the first semiconductor chip and the second semiconductor chip are logic chips.

11. The semiconductor package of claim 1, wherein the semiconductor device is a high bandwidth memory (HBM) package.

12. The semiconductor package of claim 1, further comprising a passive element arranged on a bottom surface of the first redistribution substrate.

13. A semiconductor package comprising:
a first redistribution substrate;
a first semiconductor chip arranged on the first redistribution substrate on a right side in a first direction and including through electrodes;
a first sealant arranged on the first redistribution substrate and sealing the first semiconductor chip;
first through posts arranged on the first redistribution substrate on a left side in the first direction to be side by side with the first semiconductor chip and extending through the first sealant;
a second redistribution substrate arranged on the first semiconductor chip and first through posts;
a semiconductor device arranged on the second redistribution substrate on a left side in the first direction;
a second semiconductor chip arranged on the second redistribution substrate on a right side in the first direction to be side by side with the semiconductor device; and
a second sealant arranged on the second redistribution substrate and sealing the semiconductor device and the second semiconductor chip,
wherein top surfaces of the semiconductor device and the second semiconductor chip are exposed from the second sealant.

14. The semiconductor package of claim 13, wherein the first semiconductor chip is electrically connected to the first redistribution substrate through first connection terminals arranged on a bottom surface of the first semiconductor chip, and is electrically connected to the second redistribution substrate through second connection terminals arranged on a top surface of the first semiconductor chip, and
wherein the first semiconductor chip is electrically connected to the second semiconductor chip through the second redistribution substrate and the second connection terminals.

15. The semiconductor package of claim 13, further comprising second through posts arranged on the first redistribution substrate in at least one of a right side of the first semiconductor chip in the first direction and both sides of the first semiconductor chip in a second direction perpendicular to the first direction and extending through the first sealant,
wherein the first through posts and the second through posts electrically connect the first redistribution substrate and the second redistribution substrate to each other.

16. A semiconductor package comprising:
a first redistribution substrate;
a first semiconductor chip arranged on the first redistribution substrate and including through electrodes;
a second redistribution substrate arranged on the first semiconductor chip;
a semiconductor device arranged on the second redistribution substrate on a left side in a first direction; and
a second semiconductor chip arranged on the second redistribution substrate on a right side in the first direction to be side by side with the semiconductor device.

17. The semiconductor package of claim 16, further comprising:
first through posts arranged on the first redistribution substrate on a left side in the first direction on a side of the first semiconductor chip; and
second through posts arranged on the first redistribution substrate in at least one of a right side of the first semiconductor chip in the first direction and both sides of the first semiconductor chip in a second direction perpendicular to the first direction,
wherein the first semiconductor chip is arranged on the first redistribution substrate on a right side in the first direction.

18. The semiconductor package of claim 17, wherein the first semiconductor chip is electrically connected to the first redistribution substrate through first connection terminals arranged on a bottom surface of the first semiconductor chip, and is electrically connected to the second redistribution substrate through second connection terminals arranged on a top surface of the first semiconductor chip, and
wherein the first semiconductor chip is electrically connected to the second semiconductor chip through the second redistribution substrate and the second connection terminals.

19. The semiconductor package of claim 17, further comprising:
a first sealant arranged between the first redistribution substrate and the second redistribution substrate and sealing the first semiconductor chip; and
a second sealant arranged on the second redistribution substrate and sealing the semiconductor device and the second semiconductor chip,
wherein top surfaces of the semiconductor device and the second semiconductor chip are exposed from the second sealant.

20. The semiconductor package of claim 17, wherein the semiconductor device is a high bandwidth memory (HBM) package, and
wherein the first semiconductor chip and the second semiconductor chip are logic chips.

21-26. (canceled)
